(19) United States
(12) Patent Application Publication
(10) Pub. No.: US 2018/0313962 A1
(43) Pub. Date: Nov. 1, 2018

(54) RADIATION DETECTOR AND RADIOGRAPHIC IMAGING APPARATUS

(71) Applicant: FUJIFILM CORPORATION, Tokyo (JP)

(72) Inventors: Shinichi USHIKURA, Kanagawa (JP); Keiichi AKAMATSU, Kanagawa (JP); Naoto IWAKIRI, Kanagawa (JP); Haruyasu NAKATSUGAWA, Kanagawa (JP)

(21) Appl. No.: 16/026,057

(22) Filed: Jul. 3, 2018

Related U.S. Application Data
(63) Continuation of application No. PCT/JP2018/010049, filed on Mar. 14, 2018.

(30) Foreign Application Priority Data
Mar. 22, 2017 (JP) 2017-056561
Feb. 16, 2018 (JP) 2018-025804

(51) Int. Cl. G01T 1/20; G01T 1/24; H01L 27/146; H01L 31/0248

(52) U.S. Cl. CPC G01T 1/2018; G01T 1/241; H01L 31/0248; H01L 27/146; G01T 1/246

(57) ABSTRACT

The radiation detector includes a sensor board including a flexible substrate and a layer which is provided on a first surface of the substrate and in which a plurality of pixels, which accumulate electrical charges generated in accordance with light converted from radiation, are formed; a conversion layer that is provided on a side, opposite to the substrate, of the layer in which the pixels are formed, and converts radiation into the light; a first protective film that is provided on the first surface side of the substrate with an end part also provided on the first surface side of the substrate and covers at least the entire conversion layer; and a second protective film that covers at least a second surface opposite to the first surface.

### CROSS-REFERENCE TO RELATED APPLICATIONS

This application is a continuation application of International Application No. PCT/JP2018/010049, filed on Mar. 14, 2018, the entire disclosure of which is incorporated by reference herein. Further, this application claims priority from Japanese Patent Application No. 2017-056561, filed on Mar. 22, 2017, and Japanese Patent Application No. 2018-025804, filed on Feb. 16, 2018, the entire disclosures of which are incorporated by reference herein.

### BACKGROUND

### Technical Field

The present invention relates to a radiation detector and a radiographic imaging apparatus.

### Related Art

In the related art, radiographic imaging apparatuses that perform radiographic imaging for medical diagnosis have been known. A radiation detector for detecting radiation transmitted through a subject and generating a radiation image is used for such radiographic imaging apparatuses.

As the radiation detector, there is one including a sensor board in which a conversion layer, such as a scintillator, which converts radiation into light, and a plurality of pixels that accumulate electrical charges generated in accordance with light converted in the conversion layer. As such a radiation detector, it is known that a flexible substrate is used for the sensor board (for example, refer to JP2010-85266A). By using the flexible substrate, for example, there is a case where the weight of the radiographic imaging apparatus (radiation detector) can be reduced, and imaging of a subject becomes easy.

Meanwhile, a method referred to as a coating method and a method referred to as a lamination method are known as examples of a method of manufacturing the radiation detector using the flexible substrate for the sensor board. In the coating method, a flexible substrate is formed on a supporting body, such as a glass substrate, by coating, and a sensor board and a conversion layer are further formed. Thereafter, the sensor board on which the conversion layer is formed is peeled from the supporting body by laser peeling. Meanwhile, in the lamination method, a sheet to be a flexible substrate is bonded to a supporting body, such as a glass substrate, and a sensor board and a conversion layer are further formed. Thereafter, the sensor board on which the conversion layer is formed is peeled from the supporting body by mechanical peeling.

In this way, in any of the coating method and the lamination method, a step of peeling the sensor board from the supporting body is included in a manufacturing process. However, there is a case where the sensor board is not easily peeled from the supporting body.

Meanwhile, as in the technique described in JP2010-85266A, in order to protect the substrate, the conversion layer, and the like of the sensor board, the sensor board is covered with a protective film having dampproofness. However, in a case where an attempt to facilitate the peeling of the sensor board from the supporting body is made, there is a case where the protective film is damaged, and the dampproofness degrades.

### SUMMARY

The present disclosure provides a radiation detector and a radiographic imaging apparatus capable of facilitating peeling of a sensor board from a supporting body and suppressing degradation of the dampproofness of a flexible substrate, in a manufacturing process of a radiation detector including the sensor board having the flexible substrate manufactured using the supporting body.

A radiation detector of a first aspect of the present disclosure includes: a sensor board including a flexible substrate and a layer which is provided on a first surface of the substrate and in which a plurality of pixels, which accumulate electrical charges generated in accordance with light converted from radiation, are formed; a conversion layer that is provided on a side, opposite to the substrate, of the layer in which the pixels are formed, and converts radiation into the light; a first protective film that is provided on the first surface side of the substrate with an end part also provided on the first surface side of the substrate and covers at least the entire conversion layer; and a second protective film that covers at least a second surface opposite to the first surface.

Additionally, in the radiation detector of a second aspect of the present disclosure based on the first aspect, the second protective film further covers at least an end part of the first protective film.

Additionally, in the radiation detector of a third aspect of the present disclosure based on the first aspect, the second protective film covers both the first surface and the second surface.

Additionally, in the radiation detector of a fourth aspect of the present disclosure based on the first aspect further includes a third protective film that covers at least a region excluding a region covered with the first protective film and a region covered with the second protective film.

Additionally, the radiation detector of a fifth aspect of the present disclosure based on the first aspect includes a third protective film that covers an end part of the first protective film and an end part of the second protective film.

Additionally, in the radiation detector of a sixth aspect of the present disclosure based on any one aspect of the first to fourth aspects, a side surface of the first protective film and a side surface of the substrate are flush with each other.

Additionally, in the radiation detector of a seventh aspect of the present disclosure based on any one aspect of the first to sixth aspects, the first protective film has flexibility higher than the second protective film.

Additionally, in the radiation detector of an eighth aspect of the present disclosure based on the seventh aspect, a material of the first protective film is different from a material of the second protective film.

Additionally, in the radiation detector of a ninth aspect of the present disclosure based on the seventh or eighth aspect, a density of the first protective film is lower than a density of the second protective film.

Additionally, in the radiation detector of a tenth aspect of the present disclosure based on any one aspect of the seventh to ninth aspects, a thickness of the first protective film is smaller than a thickness of the second protective film.

Additionally, the radiation detector of an eleventh aspect of the present disclosure based on any one aspect of the first to tenth aspects further comprises at least one cable of a first cable or a second cable connected to the sensor board, the first cable being connected to a drive unit that causes electrical charges to be read therethrough from the plurality of pixels, and the second cable being connected to a signal processing unit that receives an electrical signal according to the electrical charges read from the plurality of pixels and generates image data according to the received electrical signals to output the generated image data. The at least one cable is covered with the second protective film.

Additionally, in the radiation detector of a twelfth aspect of the present disclosure based on any one aspect of the first to tenth aspects, a connecting part to which at least one cable of a first cable or a second cable is connected is provided at an outer peripheral part of the substrate, the first cable being connected to a drive unit that causes electrical charges to be read therethrough from the plurality of pixels, and the second cable being connected to a signal processing unit that receives an electrical signal according to the electrical charges read from the plurality of pixels and generates image data according to the received electrical signals to output the generated image data. The first protective film covers the first surface around the connecting part.

Additionally, in the radiation detector of a thirteenth aspect of the present disclosure based on any one aspect of the first to twelfth aspects, the conversion layer includes CsI.

Additionally, a radiographic imaging apparatus of a fourteenth aspect of the present disclosure includes the radiation detector according to any one aspect of the first to thirteenth aspects of the present disclosure; a control unit that outputs a control signal for reading electrical charges accumulated in the plurality of pixels; a drive unit that outputs a driving signal for reading the electrical charges from the plurality of pixels in accordance with the control signal; and a signal processing unit receives an electrical signal according to the electrical charges read from the plurality of pixels and generates image data according to the received electrical signals to output the generated image data.

Additionally, in the radiographic imaging apparatus of a fifteenth aspect of the present disclosure based on the fourteenth aspect, the control unit and the radiation detector are provided side by side in a direction intersecting a lamination direction in which a substrate in the radiation detector, a layer in which the plurality of pixels are formed, and a conversion layer are arranged.

Additionally, the radiographic imaging apparatus of a sixteenth aspect of the present disclosure based on the fourteenth aspect may further comprise a power source unit that supplies electrical power to at least one of the control unit, the drive unit, or the signal processing unit. The power source unit, the control unit, and the radiation detector may be provided side by side in a direction intersecting a lamination direction in which a substrate in the radiation detector, a layer in which the plurality of pixels are formed, and a conversion layer are arranged.

According to the invention disclosure, in a manufacturing process of the radiation detector including the sensor board having the flexible substrate manufactured using the supporting body, peeling of the sensor board from the supporting body can be facilitated, and degradation of the dampproofness of the flexible substrate can be suppressed.

### BRIEF DESCRIPTION OF THE DRAWINGS

FIG. 1 is a block diagram illustrating an example of the configuration of main parts of an electrical system in a radiographic imaging apparatus of a first embodiment.

FIG. 2 is a plan view of the example of the radiation detector of the first embodiment as seen from a first surface side.

FIG. 3 is a cross-sectional view taken along line A-A of the radiation detector illustrated in FIG. 2.

FIG. 4 is an explanatory view describing a method for manufacturing the radiation detector illustrated in FIGS. 2 and 3.

FIG. 5 is a cross-sectional view of another example of the radiation detector of the first embodiment.

FIG. 6 is a cross-sectional view illustrating an example of a state where the radiation detector is provided within a housing in a case where the radiographic imaging apparatus of the present embodiment is applied to a surface reading type.

FIG. 7 is a cross-sectional view illustrating another example in the state where the radiation detector is provided within the housing in the case where the radiographic imaging apparatus of the present embodiment is applied to the surface reading type.

FIG. 8 is a cross-sectional view of an example of a radiation detector of a second embodiment.

FIG. 9 is a cross-sectional view of an example of a radiation detector of a third embodiment.

FIG. 10 is a cross-sectional view of another example of the radiation detector of the third embodiment.

FIG. 11 is a plan view of an example of a sensor board and a supporting body in a state before peeled from the supporting body of a fourth embodiment, as seen from a side where a first protective film is provided.

FIG. 12 is a cross-sectional view taken along line A-A of the sensor board before being peeled from the supporting body illustrated in FIG. 11.

FIG. 13 is a cross-sectional view of an example of a radiation detector of a fourth embodiment.

FIG. 14 is a cross-sectional view of an example of a radiation detector that is different from the radiation detectors of the first to fourth embodiments in terms of a region where a first protective film is provided.

FIG. 15 is a cross-sectional view of another example of a radiation detector that is different from the radiation detectors of the first to fourth embodiments in terms of the region where the first protective film is provided.

### DESCRIPTION OF EMBODIMENTS

Hereinafter, embodiments of the invention will be described in detail with reference to the drawings. In addition, the present embodiments do not limit the invention.

### First Embodiment

A radiographic imaging apparatus of the present embodiment has a function to capture a radiation image of an object to be imaged, by detecting radiation transmitted through a subject, which is an object to be imaged, and outputting image information representing a radiation image of the subject.

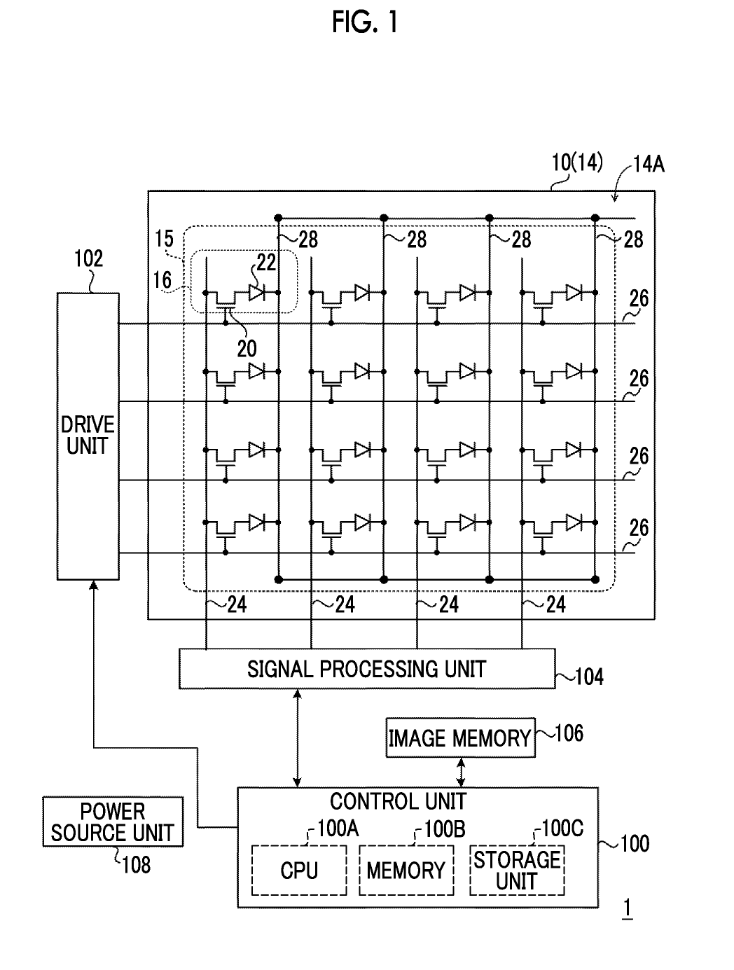

First, the outline of an example of the configuration of an electrical system in the radiographic imaging apparatus of the present embodiment will be described with reference to FIG. 1. FIG. 1 is a block diagram illustrating an example of the configuration of main parts of the electrical system in the radiographic imaging apparatus of the present embodiment.

As illustrated in FIG. 1, the radiographic imaging apparatus 1 of the present embodiment includes a radiation detector 10, a control unit 100, a drive unit 102, a signal processing unit 104, an image memory 106, and a power source unit 108.

The radiation detector 10 includes a sensor board 12 (refer to FIG. 3) and a conversion layer 30 (refer to FIG. 3) that converts radiation into light. The sensor board 12 includes a flexible substrate 14 and a plurality of pixels 16 provided on a first surface 14A of the substrate 14. In addition, in the following, the plurality of pixels 16 are simply referred to as “pixels 16”.

As illustrated in FIG. 1, each pixel 16 of the present embodiment includes a sensor part 22 that generates and accumulates an electrical charge in accordance with the light converted by the conversion layer, and a switching element 20 that reads the electrical charge accumulated in the sensor part 22. In the present embodiment, as an example, a thin film transistor (TFT) is used as the switching element 20. For that reason, in the following, the switching element 20 is referred to as a “TFT 20”. In the present embodiment, a layer in which the pixels 16 are formed on the first surface 14A of the substrate 14 is provided as a flattened layer in which the sensor parts 22 and the TFTs 20 are formed. In the following, there is a case where the layer in which the pixels 16 are formed is also referred to as the “pixels 16” for convenience of description.

The pixels 16 are two-dimensionally disposed in one direction (a scanning wiring direction corresponding to a cross direction of FIG. 1, hereinafter referred to as a “row direction”), and a direction intersecting the row direction (a signal wiring direction corresponding to the longitudinal direction of FIG. 1, hereinafter referred as a “column direction”) in an active area 15 of the sensor board 12. Although an array of the pixels 16 are illustrated in a simplified manner in FIG. 1, for example, 1024×1024 pixels 16 are disposed in the row direction and the column direction.

Additionally, a plurality of scanning wiring lines 26, which are provided for respective rows of the pixels 16 to control switching states (ON and OFF) of the TFTs 20, and a plurality of signal wiring lines 24, which are provided for respective columns of the pixels 16 and from which electrical charges accumulated in the sensor parts 22 are read, are provided in a mutually intersecting manner in the radiation detector 10. The plurality of scanning wiring lines 26 are respectively connected to a drive unit 102 via pads (not illustrated). The control unit 100 to be described below is connected to the drive unit 102, and outputs driving signals in accordance with a control signal output from the control unit 100. In the plurality of individual scanning wiring lines 26, driving signals, which are output from the drive unit 102 to drive the TFTs 20 to control the switching states thereof, flow to the plurality of scanning wiring lines 26, respectively. Additionally, the plurality of signal wiring lines 24 are respectively connected to the signal processing unit 104 via pads (not illustrated), respectively, and thereby, electrical charges read from the respective pixels 16 are output to the signal processing unit 104 as electrical signals. The signal processing unit 104 generates and outputs image data according to the received electrical signals.

The control unit 100 to be described below is connected to the signal processing unit 104, and the image data output from the signal processing unit 104 is sequentially output to the control unit 100. The image memory 106 is connected to the control unit 100, and the image data sequentially output from the signal processing unit 104 is sequentially stored in the image memory 106 under the control of the control unit 100. The image memory 106 has a storage capacity capable of storing image data equivalent to a predetermined number of sheets, and whenever radiation images are captured, image data obtained by the capturing is sequentially stored in the image memory 106.

The control unit 100 includes a central processing unit (CPU) 100A, a memory 100B including a read only memory (ROM), a random access memory (RAM), and the like, and a nonvolatile storage unit 100C, such as a flash memory. An example of the control unit 100 is a microcomputer or the like. The control unit 100 controls the overall operation of the radiographic imaging apparatus 1.

Additionally, common wiring lines 28 are provided in a wiring direction of the signal wiring lines 24 at the sensor parts 22 of the respective pixels 16 in order to apply bias voltages to the respective pixels 16. Bias voltages are applied to the respective pixels 16 from a bias power source by connecting the common wiring lines 28 to the bias power source (not illustrated) outside the sensor board 12 via a pad (not illustrated).

The power source unit 108 supplies electrical power to various elements or various circuits, such as the control unit 100, the drive unit 102, the signal processing unit 104, the image memory 106, and power source unit 108. In addition, in FIG. 1, illustration of wiring lines, which connect the power source unit 108 and various elements or various circuits together, is omitted in order to avoid complication.

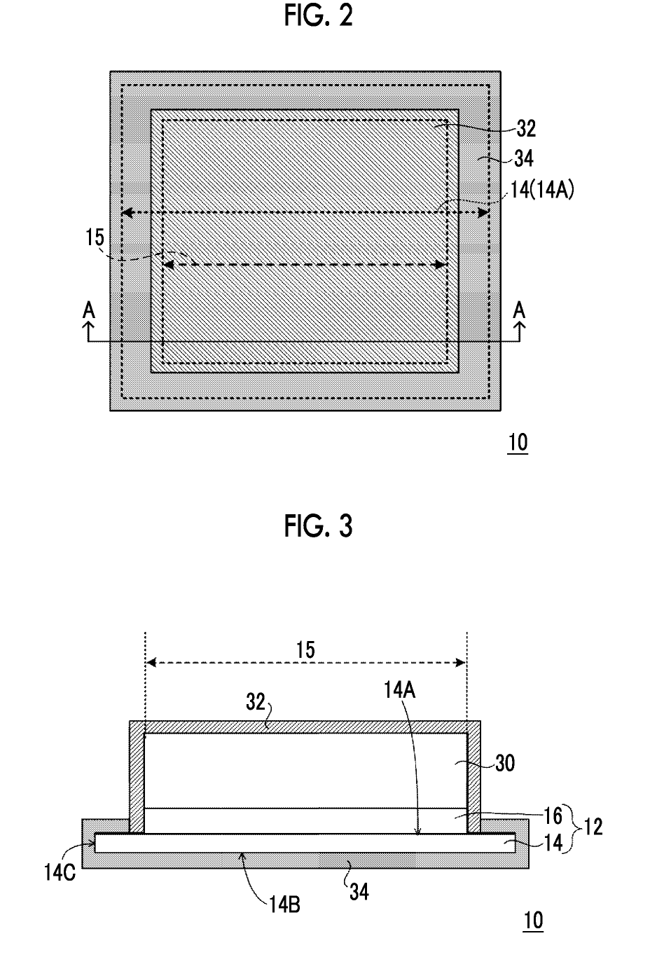

Moreover, the radiation detector 10 of the present embodiment will be described in detail. FIG. 2 is a plan view of the radiation detector 10 of the present embodiment as seen from the first surface 14A side. Additionally, FIG. 3 is a cross-sectional view taken along line A-A of the radiation detector 10 in FIG. 2.

As illustrated in FIGS. 2 and 3, the radiation detector 10 of the present embodiment includes the sensor board 12 including the substrate 14 and the pixels 16, a conversion layer 30, a protective film 32, a first protective film 32, and a second protective film 34, and the substrate 14, the pixels 16, and the conversion layer 30 are provided in this order. In addition, in the following, a direction (upward-downward direction in FIG. 3) in which the substrate 14, the pixels 16, and the conversion layer 30 are arranged is referred to as a lamination direction.

The substrate 14 is a resin sheet having flexibility and including, for example, plastics, such as polyimide. A specific example of the substrate 14 is XENOMAX (registered trademark). In addition, the substrate 14 may have any desired flexibility and is not limited to the resin sheet. For example, the substrate 14 may be a relatively thin glass substrate. The thickness of the substrate 14 may be a thickness such that desired flexibility is obtained in accordance with the hardness of a material, the size of the sensor board 12 (the area of the first surface 14A or the second surface 14B), or the like. For example, in a case where the substrate 14 is the resin sheet, the thickness thereof may be 5 μm to 125 μm. Additionally, in a case where the substrate 14 is the glass substrate, the substrate 14 has flexibility in a case where the thickness thereof becomes 0.1 mm or less in a size in which one side is about 43 cm or less. Therefore, the thickness may be 0.1 mm or less.

As illustrated in FIGS. 2 and 3, the plurality of pixels 16 are provided in an inner partial region on the first surface 14A of the substrate 14. That is, in the sensor board 12 of the present embodiment, no pixel 16 is provided at an outer peripheral part of the first surface 14A of the substrate 14. In the present embodiment, the region, on the first surface 14A of the substrate 14, where the pixels 16 are provided is used as the active area 15.

Additionally, as illustrated in FIG. 3, the conversion layer 30 covers the active area 15. In the present embodiment, a scintillator including CsI (cesium iodide) is used as an example of the conversion layer 30. It is preferable that such a scintillator includes, for example, CsI:Tl (cesium iodide to which thallium is added) or CsI:Na (cesium iodide to which sodium is added) having an emission spectrum of 400 nm to 700 nm at the time of X-ray irradiation. In addition, the emission peak wavelength in a visible light region of CsI:Tl is 565 nm.

Additionally, in the radiation detector 10 of the present embodiment, as illustrated in FIGS. 2 and 3, the first protective film 32 is provided on the first surface 14A of the substrate 14 with an end part also provided on the first surface side of the substrate, and covers the entirety of the conversion layer 30, specifically, a surface (a surface that is not in contact with the pixels 16), and a region ranging from a side surface of the conversion layer 30 to the pixels 16.

Materials of the first protective film 32 include, for example, polyethylene, polyethylene terephthalate (PET), soft vinyl chloride, an aluminum thin film, polypropylene, acrylonitrile butadiene styrene (ABS) resin, polybutyleneterephthalate (PBT), polyphenylene ether (PPE), styrene, acrylic, polyacetal, nylon, polycarbonate, and the like. As a specific instance of the first protective film 32, for example, a dampproofness film, such as a parylene (registered trademark) film, an insulating sheet (film), such as PET, or an LAPPET (registered trademark) sheet obtained by laminating aluminum, such as by bonding aluminum foil, on the insulating sheet (film), or the like.

Additionally, in the radiation detector 10 of the present embodiment, as illustrated in FIGS. 2 and 3, the second protective film 34 covers the entirety of the substrate 14, specifically, the second surface 14B of the substrate 14, a side surface 14C of the substrate 14, and a region ranging from an end part of the first surface 14A of the substrate 14 to the pixels 16 (first protective film 32).

Materials of the second protective film 34 include, for example, polyethylene, PET, soft vinyl chloride, an aluminum thin film, polypropylene, ABS resin, PBT, PPE, styrene, acrylic, polyacetal, nylon, polycarbonate, and the like. As a specific instance of the second protective film 34, for example, a dampproof film, such as a parylene film, an insulating sheet (film), such as PET, or an LAPPET sheet obtained by laminating aluminum, such as by bonding aluminum foil, on the insulating sheet (film), or the like.

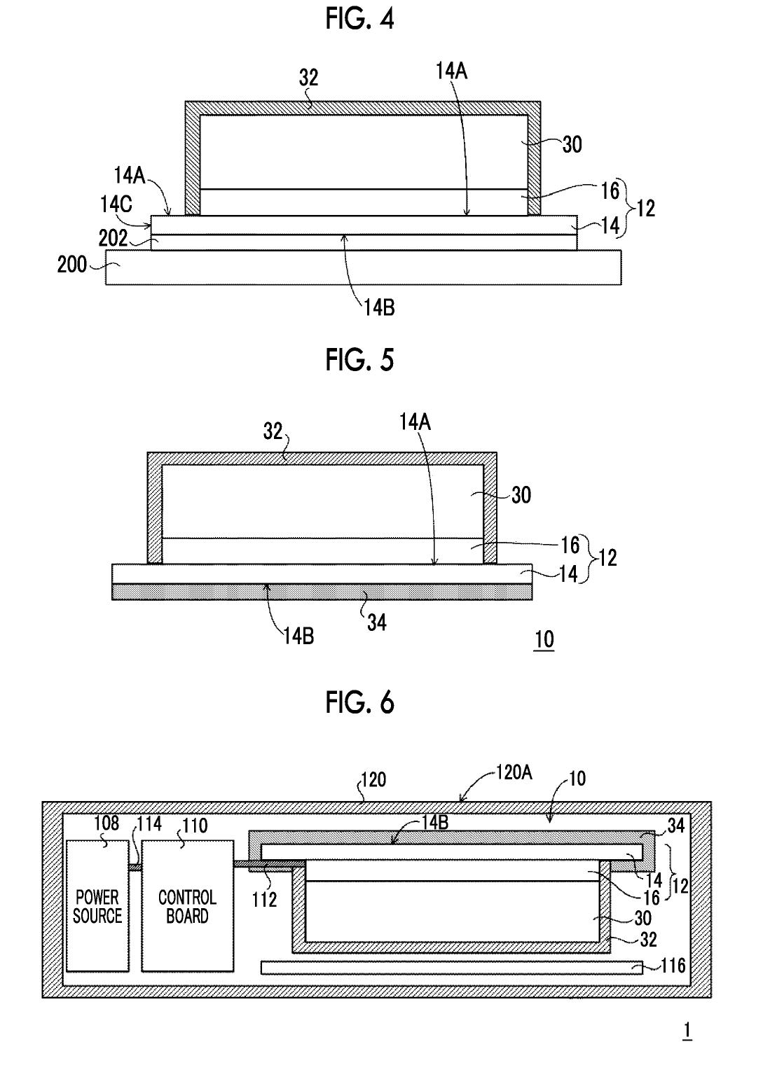

As in the radiation detector 10 illustrated in FIGS. 2 and 3, a method of manufacturing the radiation detector 10 including a sensor board 12 using a flexible substrate 14 will be described with reference to FIG. 4.

As illustrated in FIG. 4, the substrate 14 is formed on a supporting body 200, such as a glass substrate having thickness larger than that of the substrate 14, via a release layer 202. In a case where the substrate 14 is formed by the lamination method, a sheet to be the substrate 14 is bonded onto the supporting body 200. The second surface 14B of the substrate 14 is in contact with the release layer 202.

Moreover, the pixels 16 are formed on the first surface 14A of the substrate 14. In addition, in the present embodiment, as an example, the pixels 16 are formed on the first surface 14A of the substrate 14 via an undercoat layer (not illustrated) using SiN or the like.

Moreover, the conversion layer 30 is formed on the pixels 16. In the present embodiment, the conversion layer 30 of CsI is directly formed as a columnar crystal on the sensor board 12 by a vapor-phase deposition method, such as a vacuum vapor deposition method, a sputtering method, and a chemical vapor deposition (CVD) method. In this case, the side of the conversion layer 30, which in contact with the pixels 16, becomes a base point side in a growth direction of the columnar crystal.

In addition, in this way, in a case where the conversion layer 30 of CsI is directly provided on the sensor board 12 by the vapor-phase deposition method, for example, a reflective layer (not illustrated) having a function to reflect the light converted in the conversion layer 30 may be provided on the surface of the conversion layer 30 opposite to the side in contact with the sensor board 12. The reflective layer may be directly provided in the conversion layer 30, and or may be provided via an adhesion layer or the like. As a material of the reflective layer, it is preferable to use an organic material, and it is preferable to use, for example, at least one of white polyethylene terephthalate (PET), TiO₂, Al₂O₃, foamed white PET, a polyester-based high-reflection sheet, specular reflection aluminum, or the like. Particularly, it is preferable to use the white PET as the material from a viewpoint of reflectivity.

In addition, the white PET is obtained by adding a white pigment, such as TiO₂ or barium sulfate, to PET. Additionally, the polyester-based high-reflection sheet is a sheet (film) having a multilayer structure in which a plurality of thin polyester sheets are laminated. Additionally, the foamed white PET is white PET of which the surface is porous.

Additionally, in a case where the scintillator of CsI is used as the conversion layer 30, the conversion layer 30 can also be formed in the sensor board 12 by a method different from that of the present embodiment. For example, the conversion layer 30 may be formed in the sensor board 12 by preparing CsI vapor-deposited on an aluminum sheet or the like by the vapor-phase deposition method, and gluing the side of CsI, which is not in contact with the aluminum sheet, and the pixels 16 of the sensor board 12 together with an adhesive sheet or the like.

Additionally, unlike the radiation detector 10 of the present embodiment, GOS (Gd₂O₂S:Tb) or the like may be used as the conversion layer 30 instead of CsI. In this case, for example, the conversion layer 30 can be formed in the sensor board 12 by preparing a sheet glued on a support formed of the white PET or the like with an adhesion layer or the like, the sheet being obtained by dispersing GOS in a binder, such as resin, and by gluing the side of GOS on which the support is not glued, and the pixels 16 of the sensor board 12 together with an adhesive sheet or the like.

Moreover, in the radiation detector 10 of the present embodiment, the state illustrated in FIG. 4 is brought about by forming the first protective film 32 on the entirety of the conversion layer 30, specifically, the surface (the surface that is not in contact with the pixels 16) of the conversion layer 30, and the region from the side surface of the conversion layer 30 to the pixels 16, in the sensor board 12 in which the conversion layer 30 is provided.

Thereafter, the sensor board 12 provided with the conversion layer 30 and the first protective film 32 is peeled from the supporting body 200. For example, in the lamination method, mechanical peeling is performed by using any of the four sides of the sensor board 12 (substrate 14) as a starting point for peeling and gradually peeling the sensor board 12 from the supporting body 200 toward an opposite side from the side to be the starting point.

In a case where there is a difference from the radiation detector 10 of the present embodiment, that is, in a case where the formed first protective film 32 covers a region on the supporting body 200 unlike the case illustrated in FIG. 4), in the peeling of the sensor board 12, the peeling may be difficult due to the first protective film 32 that covers the supporting body 200. Particularly, in a case where the side of the sensor board 12 (substrate 14) to be the starting point for peeling is covered with the first protective film 32 up to a position on the supporting body 200, the peeling becomes difficult. Additionally, in a case where the first protective film 32 covers a region up to the supporting body 200, there is a case where an end part of the first protective film 32 is peeled from the sensor board 12 along with the peeling of the sensor board 12. In a case where the first protective film 32 is peeled from the end part of the sensor board 12, dampproofness degrades.

In contrast, in the radiation detector 10 of the present embodiment, as illustrated in FIG. 4, the first protective film 32 covers a surface and a side surface of the conversion layer 30 and side surfaces of the pixels 16 but does not cover the first surface 14A and the side surface 14C of the substrate 14. For that reason, the first protective film 32 does not cover the region on the supporting body 200.

Therefore, according to the radiation detector 10 of the present embodiment, since the side of the sensor board 12 (substrate 14) to be the starting point for peeling of the sensor board 12 is not covered with the first protective film 32, the sensor board 12 can be easily peeled. Additionally, since the peeling of the end part of the first protective film 32 from the sensor board 12 along with the peeling of the sensor board 12 can be suppressed, the degradation of the dampproofness can be suppressed.

Moreover, in the present embodiment, the radiation detector 10 of the present embodiment illustrated in FIGS. 2 and 3 is manufactured by peeling the sensor board 12 from the supporting body 200, and then, forming the second protective film 34 on the entire substrate 14, specifically, on the second surface 14B of the substrate 14, the side surface 14C of the substrate 14, and a region ranging from the end part of the first surface 14A of the substrate 14 to the pixels 16 (first protective film 32). As a method of forming the second protective film 34 on the second surface 14B of the substrate 14, for example, a parylene film may be formed by vapor deposition. Additionally, the second surface 14B of the substrate 14, the side surface 14C of the substrate 14, and the first surface 14A of ranging from the end part of the substrate 14 to the pixels 16 (first protective film 32) may be covered with, for example, a sheet-like protective film. In addition, in a case where the sheet-like protective film is used, the above entire region to be covered with the second protective film 34 may be covered with one sheet. Additionally, the above region to be covered with the second protective film 34 may be covered, for example, by sandwiching the substrate 14 with a plurality of sheets, such as sandwiching the substrate 14 with the sheets from the first surface 14A side and the second surface 14B side, respectively.

In this way, since entering of moisture from the second surface 14B of the substrate 14 may be suppressed by providing the second protective film 34 on the second surface 14B of the substrate 14, the degradation of the dampproofness of the sensor board 12 may be suppressed.

In addition, the second protective film 34 is not limited to the form illustrated in FIGS. 2 and 3, and entering of moisture from the second surface 14B can be suppressed in a case where at least the second surface 14B of the substrate 14 is covered, for example, as in the radiation detector 10 illustrated in FIG. 5.

In this way, the first protective film 32 is provided before the sensor board 12 is peeled from the supporting body 200. In a case where the sensor board 12 is peeled from the supporting body 200, the sensor board 12 is deflected. However, in a case where the flexibility of the first protective film 32 is low, there is a concern that the conversion layer 30 is damaged under the influence of the deflection of the sensor board 12. On the other hand, the second protective film 34 is provided after the sensor board 12 is peeled from the supporting body 200. For that reason, regarding the second protective film 34, as described above, the influence resulting from the deflection in a case where the sensor board 12 is peeled from the supporting body 200 may not be considered, and the impact resistance of the entire radiation detector 10 can be improved by lowering the flexibility.

Therefore, it is preferable that the first protective film 32 has high flexibility, and in the radiation detector 10 of the present embodiment, the flexibility of the first protective film 32 is higher than the flexibility of the second protective film 34.

In addition, as a method of making the flexibility of the first protective film 32 higher than the flexibility of the second protective film 34 includes, for example, forming the first protective film 32 by a material that generally has flexibility higher than the material of the second protective film 34. Specific examples of the material of the first protective film 32 in this case include, polyethylene, soft vinyl chloride, and aluminum, and a specific example of the material of the second protective film 34 include polypropylene. Moreover, for example, generally, flexibility becomes higher as the density of an object (film) becomes lower. Therefore, the density of the first protective film 32 may be made lower than the density of the second protective film 34. Moreover, for example, generally, flexibility becomes higher as the thickness of a film becomes smaller. Therefore, the density of the first protective film 32 may be made smaller than the thickness of the second protective film 34. Additionally, for example, in a case where a film is generally provided by vapor deposition, and a case where a sheet-like film is provided by bonding, the film provided by the vapor deposition has higher flexibility. Therefore, the first protective film 32 may be provided by the vapor deposition, and the second protective film 34 may be provided by bonding the sheet-like film.

In the radiographic imaging apparatus 1 to which the radiation detector 10 of the present embodiment is applied, the radiation detector 10 is provided within a housing through which radiation is transmitted and which has waterproofness, antibacterial properties, and sealability.

FIG. 6 is a cross-sectional view illustrating an example of a state where the radiation detector 10 is provided within a housing 120 in a case where the radiographic imaging apparatus 1 of the present embodiment is applied to an irradiation side sampling (ISS) type.

As illustrated in FIG. 6, the radiation detector 10, the power source unit 108, and a control board 110 are provided side by side in a direction intersecting the lamination direction within the housing 120. The radiation detector 10 is provided such that the second surface 14B of the substrate 14 faces an imaging surface 120A side of the housing 120 that is irradiated with radiation transmitted through a subject.

The control board 110 is a board in which the image memory 106, the control unit 100, and the like are formed, and is electrically connected to the pixels 16 of the sensor board 12 by a flexible cable 112 including a plurality of signal wiring lines. In addition, in the present embodiment, the control board 110 is a so-called chip on film (COF) in which the drive unit 102 and the signal processing unit 104 are provided on the flexible cable 112. However, at least one of the drive unit 102 or the signal processing unit 104 may be formed in the control board 110.

Additionally, the control board 110 and the power source unit 108 are connected together by a power source line 114.

A sheet 116 is further provided on a side to which the radiation transmitted through the radiation detector 10 is emitted, within the housing 120 of the radiographic imaging apparatus 1 of the present embodiment. The sheet 116 is, for example, a copper sheet. The copper sheet does not easily generate secondary radiation due to incident radiation, and therefore, has a function to prevent scattering to the rear side, that is, the conversion layer 30. In addition, it is preferable that the sheet 116 covers at least an entire surface of the conversion layer 30 from which radiation is emitted, and covers the entire conversion layer 30, and it is more preferable that the sheet 116 covers the entire protective film 32. In addition, the thickness of the sheet 116 may be selected in accordance with the flexibility, weight, and the like of the entire radiographic imaging apparatus 1. For example, in a case where the sheet 116 is the copper sheet and in a case where the thickness of the sheet is about 0.1 mm or more, the sheet 116 also has a function to have flexibility and shield secondary radiation that has entered the inside of the radiographic imaging apparatus 1 from the outside. Additionally, for example, in a case where the sheet 116 is the copper sheet, it is preferable that the thickness is 0.3 mm or less from a viewpoint of flexibility and weight.

The radiographic imaging apparatus 1 illustrated in FIG. 6 is able to capture a radiation image in a state where the radiation detector 10 is deflected in an out-plane direction of the second surface 14B of the substrate 14. For example, it is possible to maintain the radiation detector 10 in a deflected state in accordance with a capturing site or the like of a subject, and capture a radiation image.

In the radiographic imaging apparatus 1 illustrated in FIG. 6, since the power source unit 108 and the control board 110 are provided at a peripheral part of the housing 120 having a relatively high stiffness, the influence of external forces to be given to the power source unit 108 and the control board 110 can be suppressed.

In addition, although FIG. 6 illustrates a form in which both the power source unit 108 and the control board 110 are provided on one side of the radiation detector 10, specifically, on one side of a rectangular radiation detector 10, a position where the power source unit 108 and the control board 110 are provided is not limited to the form illustrated in FIG. 6. For example, the power source unit 108 and the control board 110 may be provided so as to be respectively decentralized onto two facing sides of the radiation detector 10, or may be provided so as to be respectively decentralized onto two adjacent sides. Additionally, in the present embodiment, FIG. 6 illustrates a form in which the power source unit 108 and the control board 110 are one component part (board). However, the invention is not limited to the form illustrated in FIG. 6. A form in which at least one of the power source unit 108 or the control board 110 is a plurality of component parts (boards) may be adopted. For example, a form in which the power source unit 108 includes a first power source unit and a second power source unit (all are not illustrated) may be adopted, or the first power source unit and the second power source unit may be provided so as to be decentralized onto two facing sides of the radiation detector 10.

In addition, in a case where the entire radiographic imaging apparatus 1 (radiation detector 10) is deflected and a radiation image is captured, the influence on the image resulting from the deflection be suppressed by performing image correction.

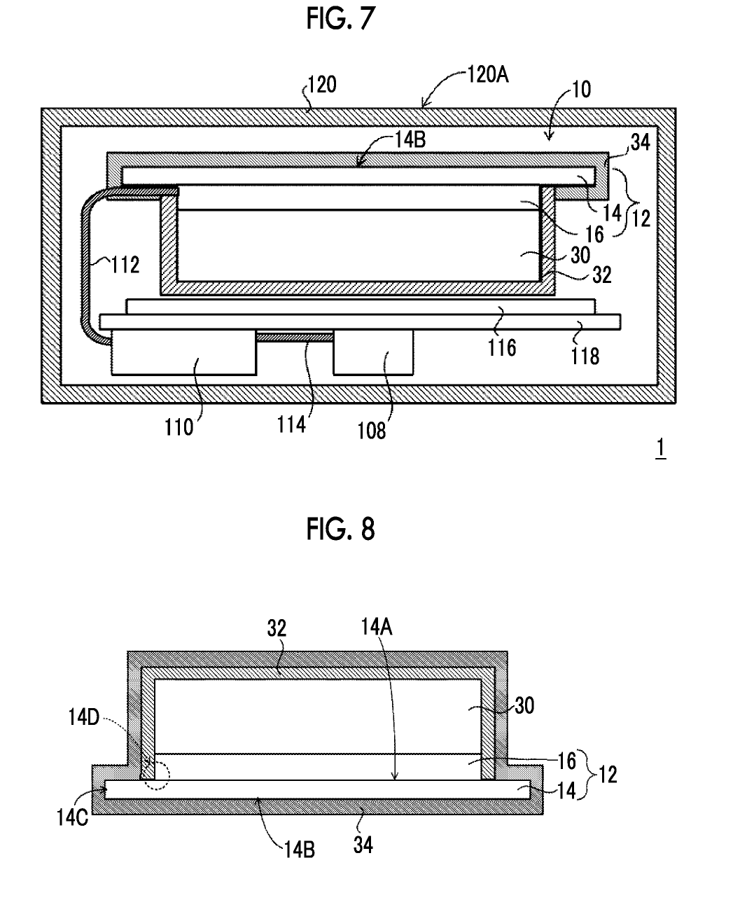

FIG. 7 is a cross-sectional view illustrating another example in a state where the radiation detector 10 is provided within the housing 120 in a case where the radiographic imaging apparatus 1 of the present embodiment is applied to the ISS type.

As illustrated in FIG. 7, the power source unit 108 and the control board 110 are provided are provided side by side in the direction intersecting the lamination direction within the housing 120, the radiation detector 10, the power source unit 108, and the control board 110 are provided side by side in the lamination direction.

Additionally, in the radiographic imaging apparatus 1 illustrated in FIG. 7, a base 118 that supports the radiation detector 10 and the control board 110 is provided between the control board 110 and the power source unit 108, and the sheet 116. For example, carbon or the like is used for the base 118.

In the radiographic imaging apparatus 1 illustrated in FIG. 7, it is possible to capture a radiation image in a state where the radiation detector 10 is slightly deflected in the out-plane direction of the second surface 14B of the substrate 14, for example, in a state where a central part thereof is deflected by about 1 mm to 5 mm. However, since the control board 110 and the power source unit 108, and the radiation detector 10 are provided in the lamination direction and the base 118 is provided, the central part is not deflected unlike the case of the radiographic imaging apparatus 1 illustrated in FIG. 6.

In this way, in the radiation detector 10 of the present embodiment, the first protective film 32 covers the entire conversion layer 30, and the first protective film 32 covers the surface and the side surface of the conversion layer 30, and the side surfaces of the pixels 16 but does not cover the first surface 14A and the side surface 14C of the substrate 14. Therefore, according to the radiation detector 10 of the present embodiment, since the side of the sensor board 12 (substrate 14) to be the starting point for peeling of the sensor board 12 is not covered with the first protective film 32, the peeling of the sensor board 12 from the supporting body 200 can be easily performed. Additionally, since the peeling of the end part of the first protective film 32 from the sensor board 12 along with the peeling of the sensor board 12 can be suppressed, the degradation of the dampproofness can be suppressed.

Additionally, in the radiation detector 10 of the present embodiment, the second protective film 34 covers the entire substrate 14. For that reason, since the entering of moisture from the second surface 14B of the substrate 14 can be suppressed, the degradation of the dampproofness can be suppressed.

### Second Embodiment

In the radiation detector 10 of the present embodiment, since the region where the second protective film 34 is provided is different from that of the radiation detector 10 of the first embodiment. Therefore, the second protective film 34 in the radiation detector 10 of the present embodiment will be described.

A cross-sectional view of an example of the radiation detector 10 of the present embodiment is illustrated in FIG. 8. As illustrated in FIG. 8, the second protective film 34 covers the sensor board 12, including the first protective film 32 that covers the conversion layer 30. Specifically, the second surface 14B of the substrate 14, the side surface 14C of the substrate 14, the first surface 14A ranging from the end part of the substrate 14 to the pixels 16 (the first protective film 32) and the entire first protective film 32 that includes the conversion layer 30 and the pixels 16 are covered. That is, the second protective film 34 covers both the first surface 14A and the second surface 14B.

Such a first protective film 32 includes, for example, a parylene film or the like. In this case, the first protective film 32 can be formed by vapor deposition.

In this way, in the radiation detector 10 of the present embodiment, the conversion layer 30 is doubly sealed with the first protective film 32 and the second protective film 34. For that reason, according to the radiation detector 10 of the present embodiment, the dampproofness performance with respect to the conversion layer 30 can be further enhanced. Particularly, CsI is vulnerable to moisture, and in a case where moisture enters the interior of the radiation detector 10, there is a concern to that the image quality of a radiation image may deteriorate. For that reason, in a case where CsI is used for the conversion layer 30, it is preferable to further enhance the dampproofness performance with respect to the conversion layer 30 as in the radiation detector 10 of the present embodiment.

Additionally, in a case where at least one of the first protective film 32 or the second protective film 34 is a parylene film, the parylene film has dampproofness lower than a sheet made of resin, it is preferable to doubly seal the conversion layer 30 as in the radiation detector 10 of the present embodiment.

Additionally, in the radiation detector 10 of the present embodiment, the second protective film 34 covers a boundary part 14D that is a boundary on the first surface 14A of the substrate 14 where the pixels 16 are formed, entering of moisture into the interior of the substrate 14 from the boundary part 14D can be suppressed. Therefore, according to the radiation detector 10 of the present embodiment, degradation of the dampproofness performance can be suppressed.

### Third Embodiment

In the present embodiment, unlike the radiation detector 10 of each of the above embodiments, a form further including a protective film that is different from the first protective film 32 and the second protective film 34 will be described.

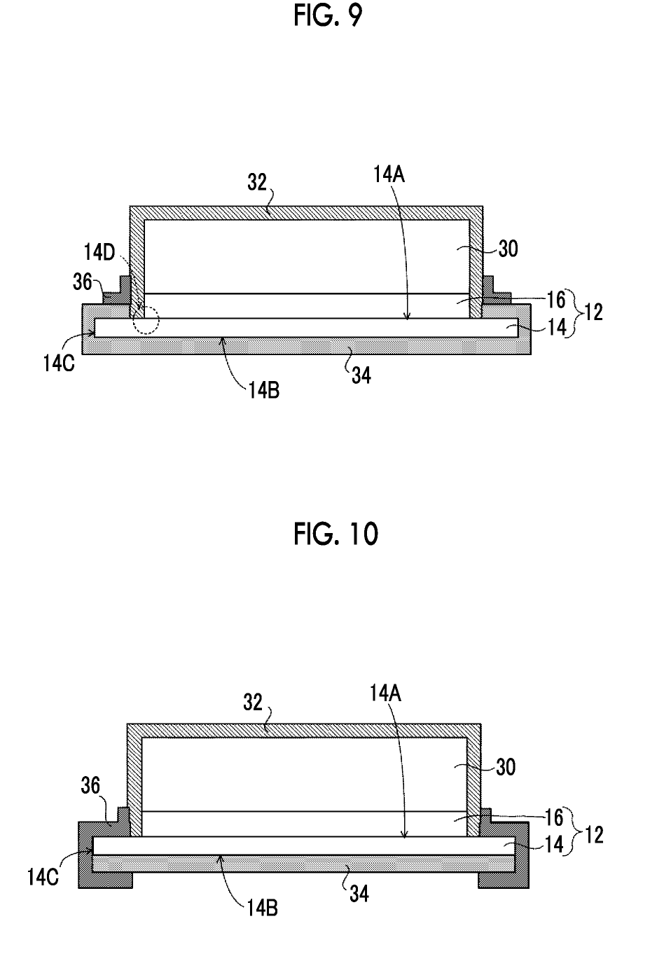

A cross-sectional view of an example of the radiation detector 10 of the present embodiment is illustrated in FIG. 9. As illustrated in FIG. 9, the radiation detector 10 of the present embodiment further includes a third protective film 36 in addition to the first protective film 32 and the second protective film 34. As illustrated in FIG. 9, the third protective film 36 covers the end part of the first protective film 32 and an end part of the second protective film 34 that are located at the boundary part 14D that is a boundary between the substrate 14 and the pixels 16.

In the radiation detector 10 of the present embodiment, in a case where the third protective film 36 covers the end part of the first protective film 32 and the end part of the second protective film 34, entering of moisture into the sensor board 12 from the end part of the first protective film 32, the end part of the second protective film 34, the boundary part between the first protective film 32 and the second protective film 34, and the like can be suppressed. Therefore, according to the radiation detector 10 of the present embodiment, the degradation of the dampproofness performance can be suppressed.

Such a third protective film 36 includes, for example, a parylene film or the like. In this case, the third protective film 36 can be formed by vapor deposition. In addition, since the third protective film 36 is provided in a bent portion (for example, the boundary part 14D in FIG. 9) of the radiation detector 10, it is preferable that the flexibility is generally high from a viewpoint of improving adhesion.

In addition, a region where the third protective film 36 is not limited to the region illustrated in FIG. 9, and may be, for example, a region according to a region where the first protective film 32 and the second protective film 34 are provided. For example, an example of a case where the third protective film 36 is provided for the radiation detector 10 illustrated in above FIG. 5 is illustrated in FIG. 10. In the radiation detector 10 illustrated in FIG. 10 (FIG. 5), a portion of the first surface 14A of the substrate 14 and the side surface 14C of the substrate 14 are not covered with either the first protective film 32 or the second protective film 34. In such a case, as illustrated in FIG. 10, it is preferable that a region including at least a region, which is not covered with either the first protective film 32 or the second protective film 34, is covered with the third protective film 36. In addition, even in this case, as illustrated in FIG. 10, it is needless to say that it is preferable to cover a region also including the end part of the first protective film 32 and the end part of the second protective film 34 with the third protective film 36. In this way, in a case where the entire radiation detector 10 is covered with at least one of the first protective film 32, the second protective film 34, and the third protective film 36, the effect of suppressing entering of moisture from the outside can be further enhanced. Therefore, the degradation of the dampproofness performance can be suppressed.

### Fourth Embodiment

In each of the above embodiments, a form in which the first protective film 32 is not uniformly provided for the first surface 14A of the substrate 14 has been described. In the present embodiment, a form that is not uniform with respect to whether or not to provide the first protective film 32 on the first surface 14A of the substrate 14 or how to provide the first protective film 32 (how to set the range of a region to be covered) will be described.

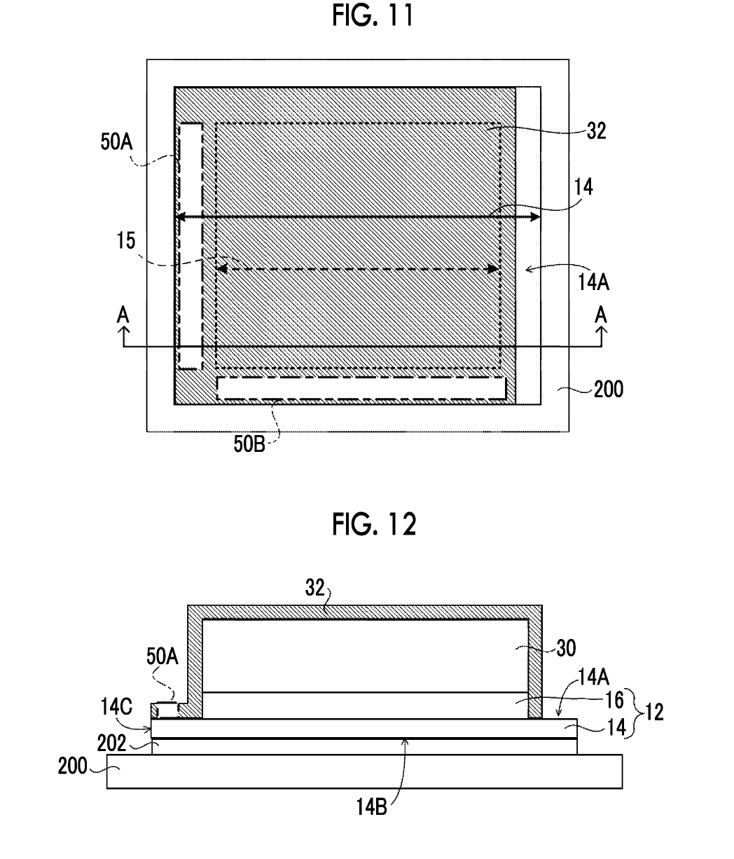

In FIG. 11, an example of the sensor board 12 and the supporting body 200 in a state before being peeled from the supporting body 200 in the present embodiment is illustrated in a plan view as seen from a side where the first protective film 32 is provided. Additionally, FIG. 12 is a cross-sectional view taken along line A-A of the sensor board 12 before being peeled from the supporting body 200 illustrated in FIG. 11.

In an example illustrated in FIG. 11, the first protective film 32 covers the first surface 14A of the substrate 14 in some sides (three sides) of an outer periphery of the sensor board 12 (substrate 14).

Additionally, in the example illustrated in FIG. 11, outer peripheral parts of two adjacent sides of the sensor board 12 are respectively provided with a terminal part 50A and a terminal part 50B to which flexible cables 112 are connected. In addition, the flexible cables 112 of the present embodiment are examples of a first cable and a second cable of the present disclosure.

As described above, the flexible cables 112 for connecting like the control board 110, the drive unit 102, and the signal processing unit 104 are connected to the sensor board 12. For that reason, as illustrated in FIG. 11, the terminal parts are provided at the outer periphery of the sensor board 12, as examples of connecting parts to which the flexible cables 112 are connected.

As illustrated in FIG. 11, in a case where the sensor board 12 includes the terminal part 50A and the terminal part 50B, it is preferable that the terminal part 50A and the terminal part 50B are not covered with the first protective film 32. In this case, the first protective film 32 may be formed in a state where the region, on the first surface 14A of the substrate 14, where the terminal part 50A and the terminal part 50B are provided is masked. In addition, a side surface at a side of the substrate 14 corresponding to an outer peripheral part where the terminal part 50A or the terminal part 50B is provided may be covered with the first protective film 32. For example, in a case where the sensor board 12 is peeled from the supporting body 200, using the side of the substrate 14 corresponding to the outer peripheral part where the terminal part 50A or the terminal part 50B is provided, as a starting point, after a flexible cable 112 is bonded to the terminal part 50A or the terminal part 50B by thermo-compression, the sensor board 12 is not easily peeled due to the flexible cable 112. Additionally, in a case where the sensor board 12 is peeled in this way, there is a case where the drive unit 102, the signal processing unit 104 or the like mounted on the flexible cable 112 is negatively affected due to peeling charging. For this reason, the side of the substrate 14 corresponding to the outer peripheral part where the terminal part 50A or the terminal part 50B is provided does not become the starting point for peeling. Therefore, even in a case where the side surface is covered with the first protective film 32, there is no possibility that the peeling of the sensor board 12 becomes difficult.

In addition, in a case where the terminal part 50A and the terminal part 50B are provided at the outer peripheral part of the first surface 14A of the substrate 14, it is preferable that the side of the substrate 14 to be the starting point for peeling from the supporting body 200 is not the side corresponding to the outer peripheral part where the terminal part 50A or the terminal part 50B is provided. Additionally, in order to facilitate the peeling of the sensor board 12 at the side of the substrate 14 to be the starting point for peeling, it is preferable that the first protective film 32 does not cover the first surface 14A. In the case illustrated in FIGS. 11 and 12, the first protective film 32 is not provided at a side opposite to the side of the substrate 14 having the terminal part 50A provided at the outer peripheral part thereof, on the first surface 14A.

In this case, after the sensor board 12 is peeled from the supporting body 200, the flexible cables 112 are connected to the terminal part 50A and the terminal part 50B. A method of connecting the flexible cables 112 includes, for example, thermocompression bonding.

After the flexible cables 112 are connected to the sensor board 12, the second protective film 34 is formed including regions that cover the flexible cables 112. An example of the radiation detector 10 in which the same second protective film 34 as that of the radiation detector 10 of the first embodiment is formed is illustrated in FIG. 13. As illustrated in FIG. 13, the portions of the flexible cables 112 connected to the sensor board 12 are not covered with the first protective film 32 but is covered with the second protective film 34.

As described above, the radiation detector 10 of each of the above embodiments includes the sensor board 12 including the flexible substrate 14, and the layer in which the plurality of pixels 16, which are provided on the first surface 14A of the substrate 14 and accumulate electrical charges generated in accordance with light converted from radiation, are formed, the conversion layer 30 that is provided on the side, opposite to the substrate 14, of the layer in which the pixels 16 are formed, and converts radiation into the light, the first protective film 32 that is provided on the first surface 14A side of the substrate 14 with the end part also provided on the first surface side of the substrate and covers at least the entire conversion layer 30, and the second protective film 34 that covers at least the second surface 14B opposite to the first surface 14A.

In this way, in the radiation detector 10 of each of the above embodiments, the side of the sensor board 12 (substrate 14) to be the starting point where the sensor board 12 is peeled from the supporting body 200 in a manufacturing process is not covered with the first protective film 32. Therefore, the peeling of the sensor board 12 from the supporting body 200 can be easily performed. Additionally, since the peeling of the end part of the first protective film 32 from the sensor board 12 along with the peeling of the sensor board 12 can be suppressed, the degradation of the dampproofness can be suppressed.

Additionally, in the radiation detector 10 of each of the above embodiments, the second protective film 34 covers the entire second surface 14B of the substrate 14. For that reason, since the entering of moisture from the second surface 14B of the substrate 14 can be suppressed, the degradation of the dampproofness can be suppressed.

Therefore, according to the radiation detector 10 of each of the above embodiments, in the manufacturing process of the radiation detector 10 including the sensor board 12 having the flexible substrate 14 manufactured using the supporting body 200, the peeling of the sensor board 12 from the supporting body 200 can be facilitated, and the degradation of the dampproofness of the flexible substrate 14 can be suppressed.

Additionally, in the radiation detector 10 of each of the above embodiment, the second protective film 34 is provided on the second surface 14B of the substrate 14. Therefore, the position, in the lamination direction, of a stress neutral plane (a plane where the stress becomes 0) formed in a case where the radiation detector 10 is deflected as a load is applied in the lamination direction can be adjusted. By the stress being applied to an interface (for example, the surface of the conversion layer 30 that faces the sensor board 12 between the sensor board 12 and the conversion layer 30, the conversion layer 30 is easily peeled from the sensor board 12. The stress applied to the above interface becomes smaller as the position, in the lamination direction, of the stress neutral plane approaches the above interface. In the radiation detector 10 of each of the above embodiments, by providing the second protective film 34, the position of the stress neutral plane can be brought closer to the above interface compared to a case where the second protective film 34 is not provided.

Therefore, according to the radiation detector 10 of each of the above embodiments, even in a case where the radiation detector 10 is deflected, the conversion layer 30 cannot be easily peeled from the sensor board 12.

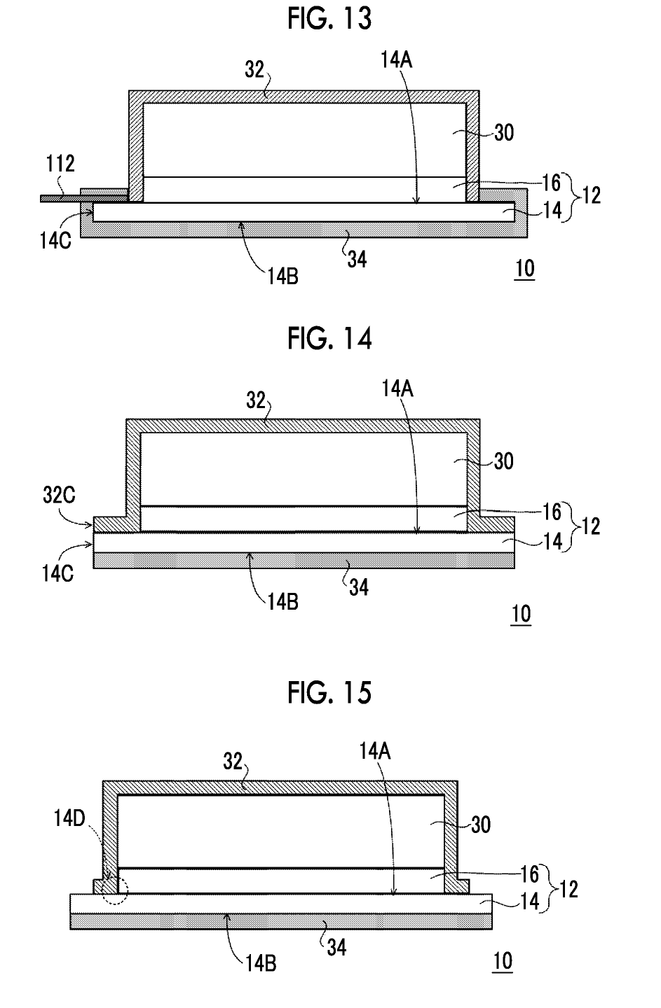

In addition, the region where the first protective film 32 is provided is not limited to that of each of the above embodiment. For example, as in the radiation detector 10 illustrated in FIG. 14, the entire region of the first surface 14A of the substrate 14 where the pixels 16 are not provided may be covered with the first protective film 32. In the case illustrated in FIG. 14, a side surface 32C of the first protective film 32 and the side surface 14C of the substrate 14 become flush with each other. In addition, the term “flush” means a state where the end part of the first protective film 32 and the end part of the substrate 14 are aligned with each other, and means the side surface 32C of the first protective film 32 and the side surface 14C of the substrate 14 include a slight difference and are regarded as being on the same plane. Even in the radiation detector 10 in this case, since the first protective film 32 does not cover a portion up to the supporting body 200 in which the sensor board 12 is formed in the manufacturing process, the peeling of the sensor board 12 from the supporting body 200 can be facilitated.

Additionally, as in the radiation detector 10 illustrated in FIG. 15, the end part of the first protective film 32 may cover the region of the first surface in the vicinity of the boundary part 14D] 14A with the first protective film 32 by being bent at the boundary part 14D that is the boundary between the substrate 14 and the pixels 16.

In addition, in the radiation detector 10 illustrated in the radiation detector 10 illustrated in FIGS. 14 and 15, it is needless to say that the region of the substrate 14, which is not covered with either the first protective film 32 or the second protective film 34, such as the side surface of the substrate 14, may be covered with the third protective film 36 as in the radiation detector 10 of the above third embodiment.

Additionally, in each of the above embodiments, a form in which the radiation detector 10 is manufactured by the lamination method has been described. However, the invention is not limited to this form. Even in a form that but manufactures the radiation detector 10 by the coating method, the first protective film 32 does not cover the starting point for peeling, and the second protective film 34 covers the second surface 14B of the substrate 14. Accordingly, the effects that the peeling of the sensor board 12 from the supporting body 200 can be facilitated and the degradation of the dampproofness can be suppressed are obtained.

Additionally, a case where the radiation detector 10 (radiographic imaging apparatus 1) is applied to the ISS type has been described in each of the above embodiments. However, the radiation detector 10 (radiographic imaging apparatus 1) may be applied to a so-called “penetration side sampling (PSS) type” in which the sensor board 12 is disposed on a side opposite to a side that the radiation of the conversion layer 30 enters.

Additionally, in each of the above embodiments, as illustrated in FIG. 1, an aspect in which the pixels 16 are two-dimensionally arrayed in a matrix has been described. However, the pixels 16 may be one-dimensionally arrayed or may be arrayed in a honeycomb arrangement. Additionally, the shape of the pixels is also not limited, and may be a rectangular shape, or may be a polygonal shape, such as a hexagonal shape. Moreover, it goes without saying that that the shape of the active area 15 is also not limited.

In addition, it goes without saying that the configurations, manufacturing methods, and the like of the radiographic imaging apparatuses 1, the radiation detectors 10, and the like that are described in the respective above embodiments are merely examples, and can be modified in accordance with situations without departing from the scope of the invention.

The disclosure of JP2017-056561 filed on Mar. 22, 2017, and the disclosure of JP2018-025804 filed on Feb. 16, 2018 are incorporated into the preset specification by reference in its entirety.

All documents, patent applications, and technical standards described in the present specification are incorporated in the present specification by reference in their entireties to the same extent as in a case where the individual documents, patent applications, and technical standards are specifically and individually written to be incorporated by reference.

What is claimed is:

1. A radiation detector comprising:
a sensor board including a flexible substrate and a layer which is provided on a first surface of the substrate and in which a plurality of pixels, which accumulate electrical charges generated in accordance with light converted from radiation, are formed;
a conversion layer that is provided on a side, opposite to the substrate, of the layer in which the pixels are formed, and converts radiation into the light;
a first protective film that is provided on the first surface side of the substrate with an end part also provided on the first surface side of the substrate and covers at least the entire conversion layer; and
a second protective film that covers at least a second surface opposite to the first surface.

2. The radiation detector according to claim 1, wherein the second protective film further covers at least an end part of the first protective film.

3. The radiation detector according to claim 1, wherein the second protective film covers both the first surface and the second surface.

4. The radiation detector according to claim 1, further comprising a third protective film that covers at least a region excluding a region covered with the first protective film and a region covered with the second protective film.

5. The radiation detector according to claim 1, further comprising a third protective film that covers an end part of the first protective film and an end part of the second protective film.

6. The radiation detector according to claim 1, wherein a side surface of the first protective film and a side surface of the substrate are flush with each other.

7. The radiation detector according to claim 1, wherein the first protective film has flexibility higher than the second protective film.

8. The radiation detector according to claim 7, wherein a material of the first protective film is different from a material of the second protective film.

9. The radiation detector according to claim 7, wherein a density of the first protective film is lower than a density of the second protective film.

10. The radiation detector according to claim 7, wherein a thickness of the first protective film is smaller than a thickness of the second protective film.

11. The radiation detector according to claim 1, further comprising:
at least one cable of a first cable or a second cable connected to the sensor board, the first cable being connected to a drive unit that causes electrical charges to be read therethrough from the plurality of pixels, and the second cable being connected to a signal processing unit that receives an electrical signal according to the electrical charges read from the plurality of pixels and generates image data according to the received electrical signals to output the generated image data,
wherein the at least one cable is covered with the second protective film.

12. The radiation detector according to claim 1,
wherein a connecting part to which at least one cable of a first cable or a second cable is connected is provided at an outer peripheral part of the substrate, the first cable being connected to a drive unit that causes electrical charges to be read therethrough from the plurality of pixels, and the second cable being connected to a signal processing unit that receives an electrical signal according to the electrical charges read from the plurality of pixels and generates image data according to the received electrical signals to output the generated image data,
wherein the first protective film covers the first surface around the connecting part.

13. The radiation detector according to claim 1, wherein the conversion layer includes CsI.

14. A radiographic imaging apparatus comprising:
the radiation detector according to claim 1;
a control unit that outputs a control signal for reading electrical charges accumulated in the plurality of pixels;
a drive unit that outputs a driving signal for reading the electrical charges from the plurality of pixels in accordance with the control signal; and
a signal processing unit that receives an electrical signal according to the electrical charges read from the plurality of pixels and generates image data according to the received electrical signals to output the generated image data.

15. The radiographic imaging apparatus according to claim 14, wherein the control unit and the radiation detector are provided side by side in a direction intersecting a lamination direction in which a substrate in the radiation detector, a layer in which the plurality of pixels are formed, and a conversion layer are arranged.

16. The radiographic imaging apparatus according to claim 14, further comprising:
a power source unit that supplies electrical power to at least one of the control unit, the drive unit, or the signal processing unit,
wherein the power source unit, the control unit, and the radiation detector are provided side by side in a direction intersecting a lamination direction in which a substrate in the radiation detector, a layer in which the plurality of pixels are formed, and a conversion layer are arranged.
